(19) United States
(12) Patent Application Publication
(10) Pub. No.: US 2026/0136658 A1
(43) Pub. Date: May 14, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Zhi-Chang LIN, Hsinchu County (TW); Che Chi SHIH, Taoyuan City (TW); Tsung-Kai CHIU, Hsinchu County (TW)

(73) Assignee: TAIWAN SEMICONDUCTOR MANUFACTURING COMPANY, LTD., Hsinchu (TW)

(21) Appl. No.: 18/941,356

(22) Filed: Nov. 8, 2024

(51) Int. Cl. H01L 27/092; H01L 21/8238; H01L 29/06; H01L 29/423; H01L 29/775; H01L 29/786

(52) U.S. Cl. CPC H10D 84/856; H10D 84/0179; H10D 84/0188; H10D 84/038; H10D 30/43; H10D 30/6735; H10D 30/6757; H10D 62/121

(57) ABSTRACT

A method includes forming a first semiconductor layer over a substrate and a second semiconductor layer stacked above the first semiconductor layer; epitaxially growing first source/drain epitaxy structures from opposite ends of the first semiconductor layer; forming a first isolation structure covering the first source/drain epitaxy structures; forming a seed layer over the first isolation structure; epitaxially growing second source/drain epitaxy structures from opposite ends of the second semiconductor layer and from a top surface of the seed layer; and forming a first gate structure wrapping around at least one of the first semiconductor layers and a second gate structure wrapping around at least one of the second semiconductor layers.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 12B illustrate a method in various stages of forming a power amplifier in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

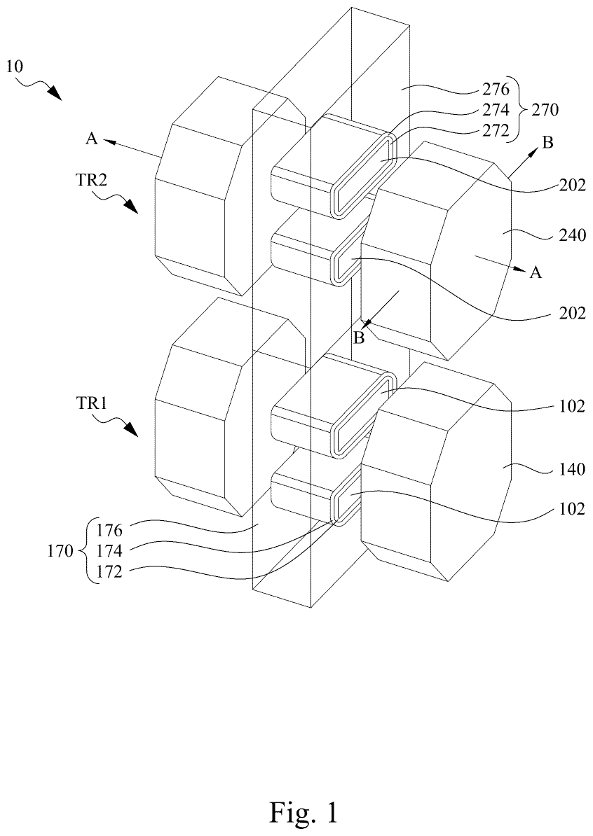

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FETs. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type and the second transistor TR2 has a second conductivity type different from the first conductivity type. For example, the first transistor TR1 is a P-type transistor, and the second transistor TR2 is an N-type transistor. Alternatively, the first transistor TR1 is an N-type transistor, and the second transistor TR2 is P-type transistor.

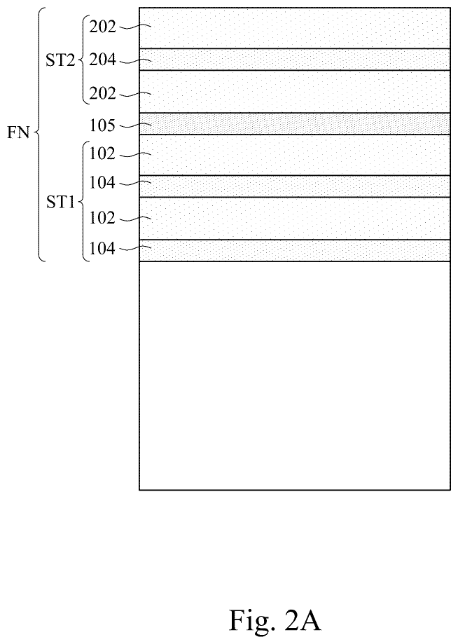

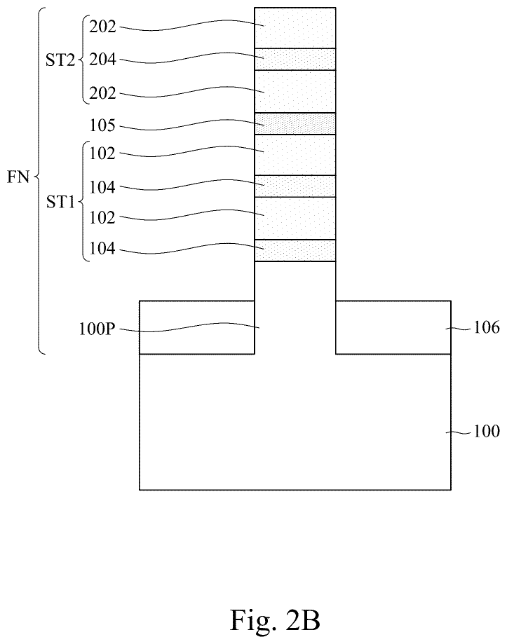

FIGS. 2A to 12B illustrate a method in various stages of forming a power amplifier in accordance with some embodiments of the present disclosure. It is noted that FIGS. 2A to 12A include cross-sectional views the same as the cross-sectional view taken along line A-A of FIG. 1, and FIGS. 2B to 12B include cross-sectional views the same as the cross-sectional view taken along line B-B of FIG. 1. The cross-sectional views of FIGS. 2A to 12A may be substantially perpendicular to the cross-sectional views of FIGS. 2B to 12B. Although FIGS. 2A to 12B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 12B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A fin structure FN is formed over the substrate 100. The fin structure FN includes a semiconductor strip 100P, a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers. In the depicted embodiments, the numbers of the semiconductor layers 102 and 202 are both two, while the disclosure is not limited thereto. In other embodiments, the numbers of the semiconductor layers 102 and 202 may be greater than 2, and the numbers of the semiconductor layers 102 and 202 may also be different.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

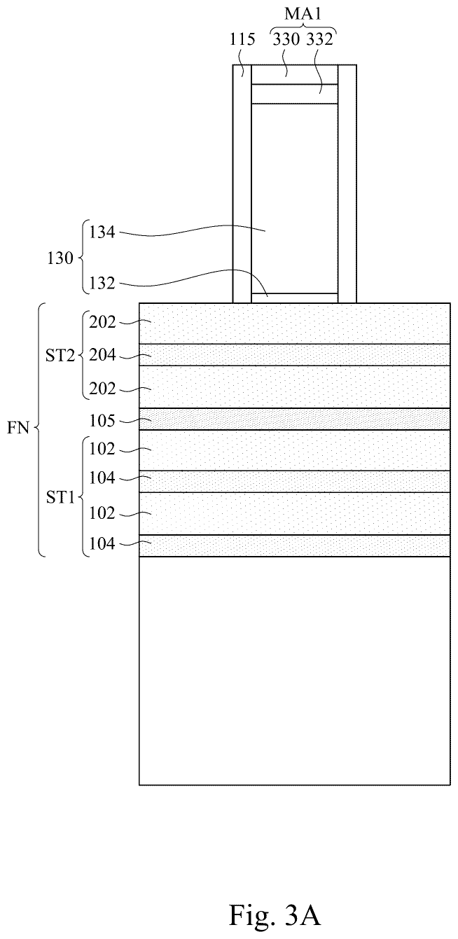

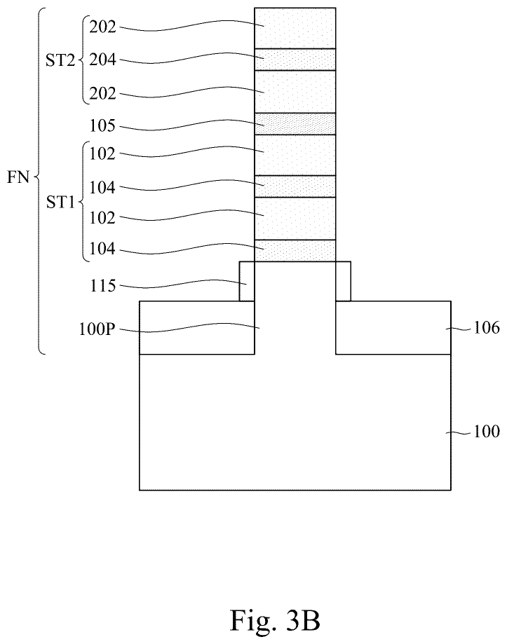

Reference is made to FIGS. 3A and 3B. A dummy gate structure 130 is formed over the substrate 100 and crossing the fin structure FN. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming a patterned mask MA1 over the dummy gate layer, and then performing an etching process to the dummy dielectric layer and the dummy gate layer by using the patterned mask MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, the patterned mask MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of the dummy gate structure 130 and on opposite sidewalls of the fin structure FN. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130 and on sidewalls of the fin structure FN. In some embodiments, portions of the spacers 115 on sidewalls of the dummy gate structures 130 can be referred to as gate spacers, and the portions of the spacers 115 on sidewalls of the fin structure FN can be referred to as fin spacers. In some embodiments, the spacer layer may be deposited using techniques such CVD, ALD, or the like.

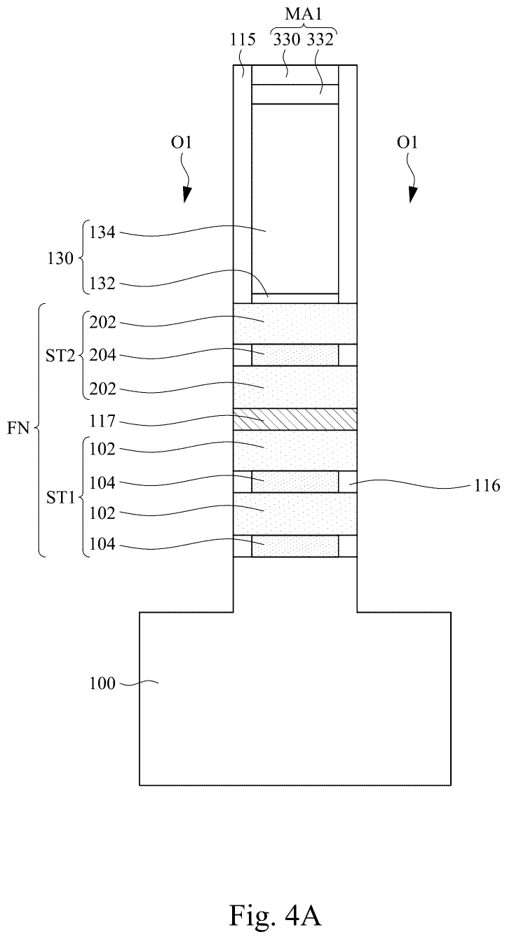

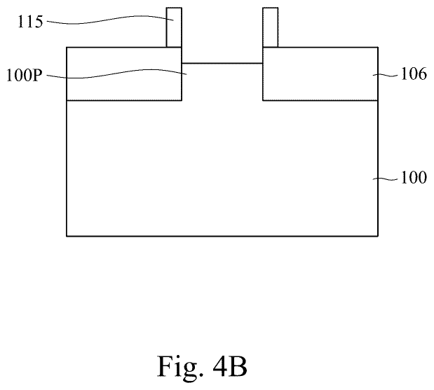

Reference is made to FIGS. 4A and 4B. An etching process is performed to remove portions of the fin structure FN by using the dummy gate structure 130 and the gate spacers 115 as etch mask, so as to form source/drain openings O1 in the fin structure FN. In some embodiments, the etching process may be wet etch, dry etch, or combinations thereof.

After the source/drain openings O1 are formed, inner spacers 116 are formed on opposite ends of each of the semiconductor layers 104 and 204, and the semiconductor layer 105 is replaced with an isolation layer 117. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

The inner spacers 116 and the isolation layer 117 can be formed by, for example, performing an etching process to laterally etch the semiconductor layers 104 and 204 to form sidewall recesses, and to remove the semiconductor layer 105 to form a gap. In some embodiments, the sidewalls of the semiconductor layers 104, 105, and 204 may be etched using isotropic etching processes, such as wet etching or the like. In some embodiments where the semiconductor layers 104, 105, and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104, 105, and 204. In some embodiments, because the semiconductor layer 105 may include different germanium concentration than the semiconductor layers 104 and 204, the etchant of the etching process may be selected such that the etching process includes a higher etch rate to the semiconductor layer 105 than to the semiconductor layers 104 and 204. As a result, the semiconductor layer 105 can be removed, while the semiconductor layers 104 and 204 are slightly etched to form the sidewall recesses. Then, inner spacers 116 are formed in the sidewall recesses on opposite ends of each of the semiconductor layers 104 and 204, and the isolation layer 117 is formed in the gap. In some embodiments, the inner spacers 116 and the isolation layer 117 may be formed by, for example, depositing a dielectric material blanket over the substrate 100 and filling the sidewall recesses and the gap, and then performing an anisotropic etching to remove portions of the dielectric material outside the sidewall recesses and the gap, leaving the remaining portions of the dielectric material in the sidewall recesses and the gap as the inner spacers 116 and the isolation layer 117, respectively.

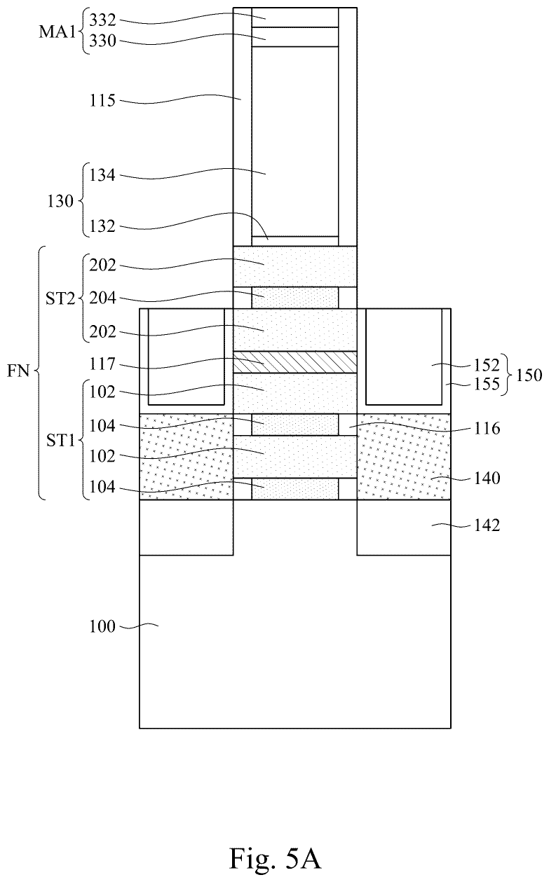

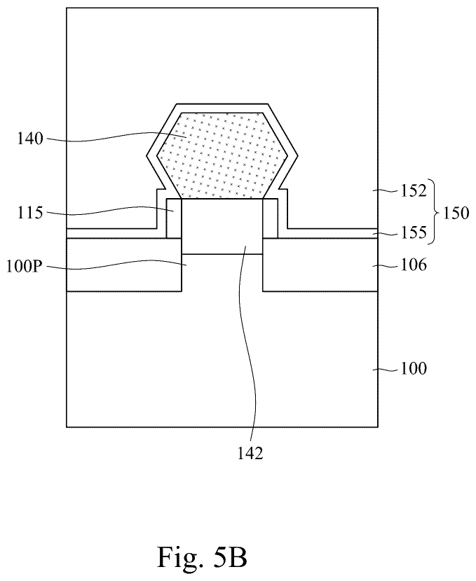

Reference is made to FIGS. 5A and 5B. Epitaxy layers 142 are formed at bottoms of the source/drain openings O1, and first source/drain epitaxy structures 140 are formed over the respective epitaxy layers 142 and on opposite ends of the exposed semiconductor layer 102. In some embodiments, the formation of the epitaxy layers 142 may include a plurality of deposition cycles, in which each deposition cycle may include a selective epitaxial growth (SEG) process and an etching process. In some embodiments, the SEG process may selectively grow a semiconductor material on exposed semiconductor surfaces, such as the exposed surfaces of the semiconductor strips 100P and the exposed surfaces of the semiconductor layers 102. However, because the exposed areas of the semiconductor strips 100P are greater than the exposed area of each of the semiconductor layers 102, the semiconductor material may include higher growing rate on the exposed areas of the semiconductor strips 100P than on the exposed area of each of the semiconductor layers 102. That is, a greater amount of the semiconductor material will be grown on the exposed areas of the semiconductor strips 100P than on the exposed area of each of the semiconductor layers 102. As a result, the etching process in each deposition cycle of the epitaxy layers 142 may remove portions of the semiconductor material formed on the exposed area of each of the semiconductor layers 102, while portions of the semiconductor material may remain over the semiconductor strips 100P after the etching process. Accordingly, performing several deposition cycles may allow a bottom-up deposition for the epitaxy layers 142. That is, the epitaxy layers 142 may be formed from the bottoms of the source/drain openings O1 via a bottom-up manner.

In some embodiments, the first source/drain epitaxy structures 140 may include semiconductor material, such as silicon germanium (SiGe), or other suitable semiconductor material. In some embodiments, the first source/drain epitaxy structures 140 may be formed by a selective epitaxial growth (SEG) process. The SEG process may selectively grow a semiconductor material on exposed semiconductor surfaces, such as the exposed surfaces of the semiconductor layer 102. In some embodiments, during forming the first source/drain epitaxy structures 140, a protective layer may be formed covering the semiconductor layers 202, such that the SEG process would not grow a semiconductor material from surfaces of the semiconductor layers 202. In some embodiments, the first source/drain epitaxy structures 140 may be doped with p-type dopants, such as boron (B), gallium (Ga), indium (In), aluminium (Al), or the like. In other embodiments, the first source/drain epitaxy structures 140 may be doped with n-type dopants, such as n-type dopants, such as phosphorus (P), arsenic (As), or antimony (Sb), or the like. In the depicted embodiments, the first source/drain epitaxy structure 140 is illustrated as having a planar top surface, while the disclosure is not limited thereto. In other embodiments, the top surface of the first source/drain epitaxy structure 140 may be non-planar.

A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152 to a position, such that at least the topmost one of the semiconductor layers 202 are exposed through the source/drain openings O1. In some embodiments, the CESL 155 and the ILD layer 152 can be collectively referred to as an isolation structure 150. In some embodiments, the topmost one of the semiconductor layers 102 and the bottommost one of the semiconductor layers 202 may be covered by the isolation structure 150. In the depicted embodiments, the bottom surface of the CESL 155 is coplanar with the bottom surface of the topmost semiconductor layer 102, while the disclosure is not limited thereto. In other embodiments, the bottom surface of the CESL 155 may be higher than or lower than the bottom surface of the topmost semiconductor layer 102.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide. The CESL 155 and the ILD layer 152 can be formed using, for example, CVD, ALD or other suitable techniques.

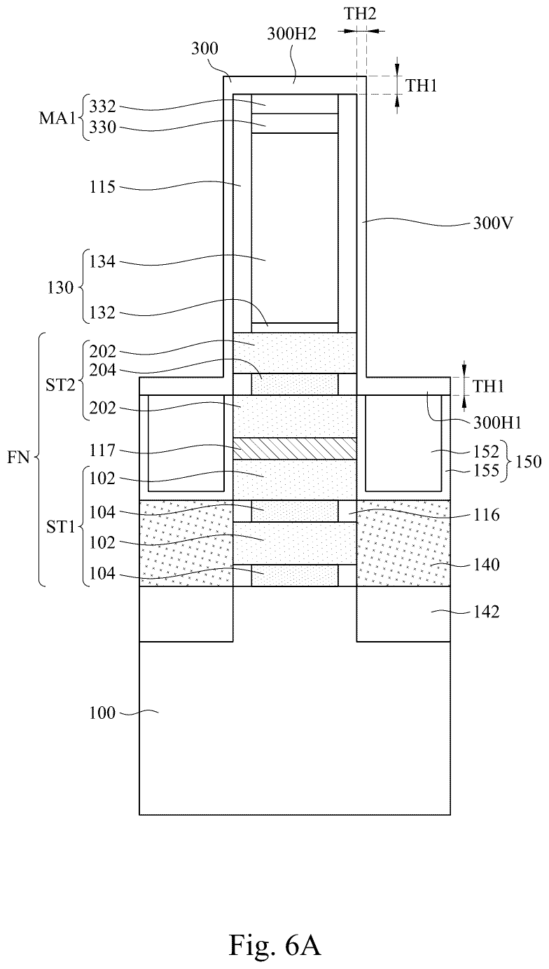

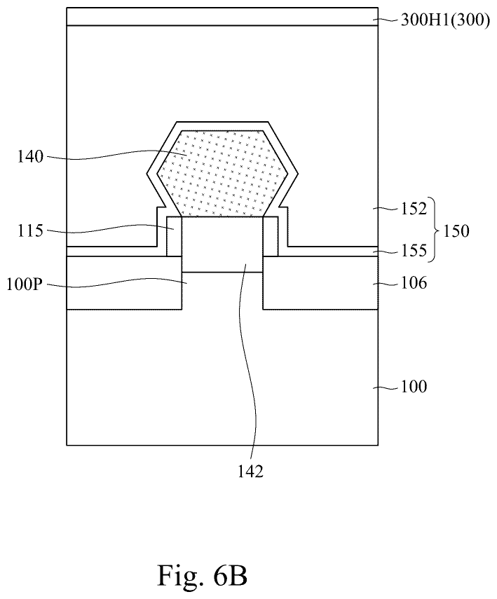

Reference is made to FIGS. 6A and 6B. A seed layer 300 is deposited blanket over the substrate 100. In greater detail, the seed layer 300 may extend from top surface of the isolation structure 150, passing through the inner spacers 116, the semiconductor layer 202, the spacers 115, to top surface of the patterned mask MA1. In some embodiments, the seed layer 300 may be made of an epitaxial semiconductor material. Exemplary epitaxial semiconductor material may include a silicon-containing material, such silicon (Si), silicon compound, or the like. In some embodiments where the seed layer 300 is an epitaxial semiconductor material, the seed layer 300 may include amorphous structure. In some embodiments, the seed layer 300 may be un-doped.

In other embodiments, the seed layer 300 may be made of a metal-containing layer, such as a single element metal or metal compound. In some embodiments, the metal compound may include metal oxide, or the like. In some embodiment where the seed layer 300 is a metal-containing layer, the seed layer 300 may include a similar crystalline structure or a similar lattice constant as the following formed epitaxy structures (e.g., the second source/drain epitaxy structures 240), which is beneficial for the epitaxial growth of the following formed epitaxy structures.

The seed layer 300 may include horizontal portions extending along the horizontal surfaces of the underlying structure and vertical portions along the vertical surfaces of the underlying structure. For example, the seed layer 300 may include horizontal portions 300H1 extending along the horizontal surfaces of the isolation structures 150 and a horizontal portion 300H2 extending along the horizontal surface of the patterned mask MA1. In greater detail, the horizontal portions 300H1 of the seed layer 300 may be in contact with the ILD layer 152 and the CESL 155 of the respective isolation structures 150. The seed layer 300 further include vertical portions 300V extending along the spacers 115, in which each vertical portion 300V may connect the horizontal portion 300H2 to a respective horizontal portion 300H1. In greater detail, each of the vertical portions 300V may extend along a sidewall of the spacer 115, a sidewall of the semiconductor layer 202, and a sidewall of the inner spacer 116.

In some embodiments, the horizontal portions 300H1 and 300H2 may include a different thickness than the vertical portions 300V. In greater detail, thicknesses of the horizontal portions 300H1 and 300H2 may be greater than thicknesses of the vertical portions 300V. For example, the horizontal portions 300H1 and 300H2 may include thickness TH1, and the vertical portions 300V may include thickness TH2, in which the thickness TH1 is greater than the thickness TH2. Here, the thicknesses of the horizontal portions 300H1 and 300H2 may be the thicknesses of the horizontal portions 300H1 and 300H2 measured along the vertical direction, while the thicknesses of the vertical portions 300V may be the thicknesses of the vertical portions 300V measured along the horizontal direction.

The thickness variation of the seed layer 300 can be achieved by using suitable deposition process, such as a directional-dependent deposition process. For example, the directional-dependent deposition can be a physical vapor deposition (PVD), a selective chemical vapor deposition (CVD), or another deposition technique. The directional-dependent deposition deposits the material of the seed layer 300 with a varying thickness as a function of an orientation of the supporting surface on which the seed layer 300 is deposited. For example, the thickness of the seed layer 300 can depend on the slope angle of a tangent (generally, “slope angle”) of the supporting surface with respect to a horizontal or major plane or orientation of the underlying semiconductor substrate 100, such as a 0° slope angle would indicate a horizontal surface, and a 90° slope angle would indicate a vertical surface in the illustrations. In some embodiments, the seed layer 300 is deposited with a greatest thickness on a horizontal surface (e.g., 0° slope angle) and with a smallest thickness on a vertical surface (e.g., 90° slope angle).

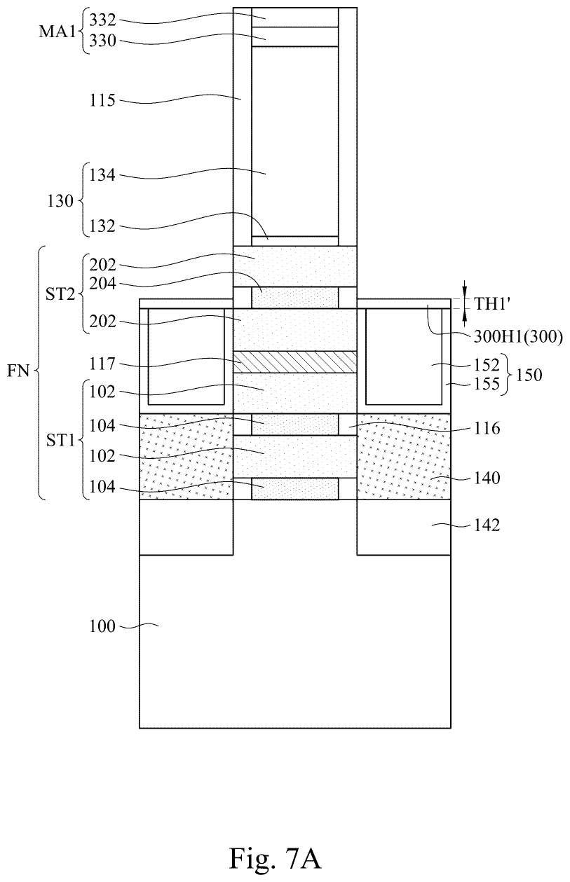

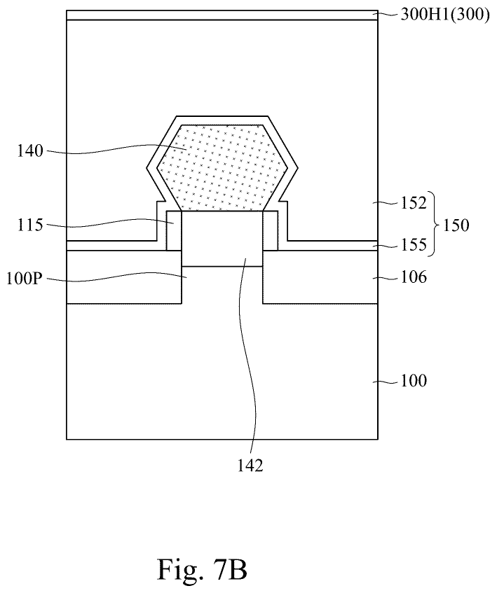

Reference is made to FIGS. 7A and 7B. An etching process is performed to the seed layer 300, so as to remove the horizontal portion 300H2 and the vertical portions 300V of the seed layer 300, while leaving the horizontal portion 300H1 remaining over the isolation structures 150 after the etching process is complete. After the etching process is complete, the patterned mask MA1, the spacers 115, the semiconductor layer 202, and the inner spacers 116 may be exposed, while the isolation structures 150 are remained covered by the horizontal portion 300H1. The horizontal portion 300H1 of the seed layer 300 is spaced apart from the topmost semiconductor layer 202.

The etched horizontal portion 300H1 of the seed layer 300 may be in contact with one of the inner spacer 116. In some embodiments, the etched horizontal portion 300H1 of the seed layer 300 may be thinner than the inner spacer 116 along the vertical direction. In some embodiments, the top surface of the etched horizontal portion 300H1 of the seed layer 300 may be lower than the top surface of the inner spacer 116, and may be lower than the bottom surface of the topmost semiconductor layer 202.

In some embodiments, the etching process may include an isotropic etching, such as a wet etch, such that the etching process may include substantially uniform etch rate on the horizontal portions 300H1 and 300H2 and the vertical portions 300V. Therefore, the etching process may be stopped once the vertical portions 300V of the seed layer 300 are removed. Because the horizontal portion 300H1 is thicker than the vertical portions 300V, the horizontal portion 300H1 will remain when the etching process is stopped. Such etching process which is terminated after a predetermined amount of time is referred to as a “timed etch.” In some embodiments, the horizontal portion 300H1 may also be etched during the etching process, and thus the remaining horizontal portion 300H1 may include thicknesses TH1′ that is less than the thicknesses TH1. It is noted that because the horizontal portion 300H2 is at the topmost position of the structure, such region may be exposed to a larger amount of etchant. Accordingly, although the horizontal portion 300H2 is thicker than the vertical portions 300V, the horizontal portion 300H2 may also be removed after the etching process is complete.

In some embodiments, the deposition process as discussed in FIGS. 6A and 6B and the etching process as discussed in FIGS. 7A and 7B can be referred to as a formation cycle of the seed layer 300. For example, a formation cycle may include a deposition process to form a seed layer blanket over the substrate, and an etching process to remove vertical portions of the seed layer. In some embodiments, the deposition cycle can be performed only one time. However, in other embodiments, the deposition cycle can be performed several times (e.g. more than one time) to achieve a desired thickness of the seed layer 300.

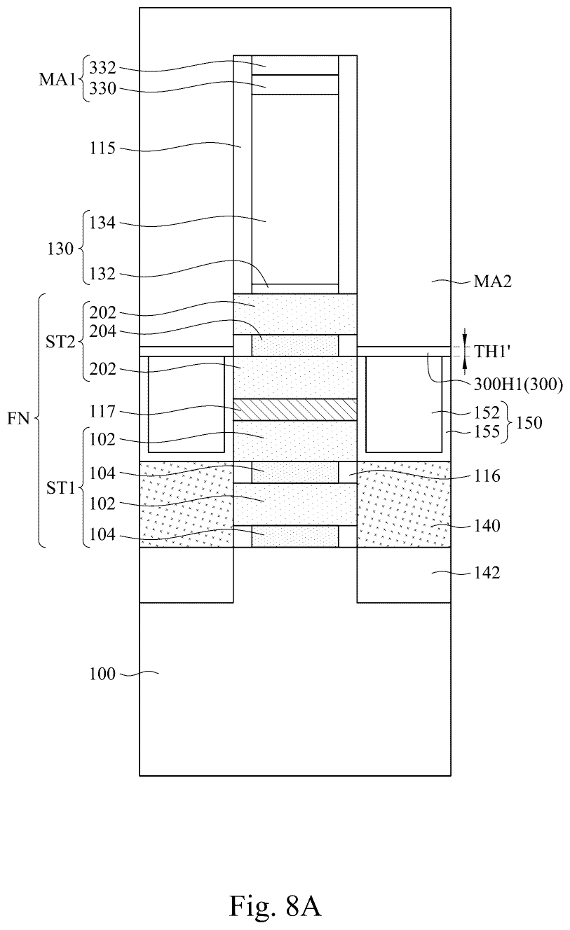

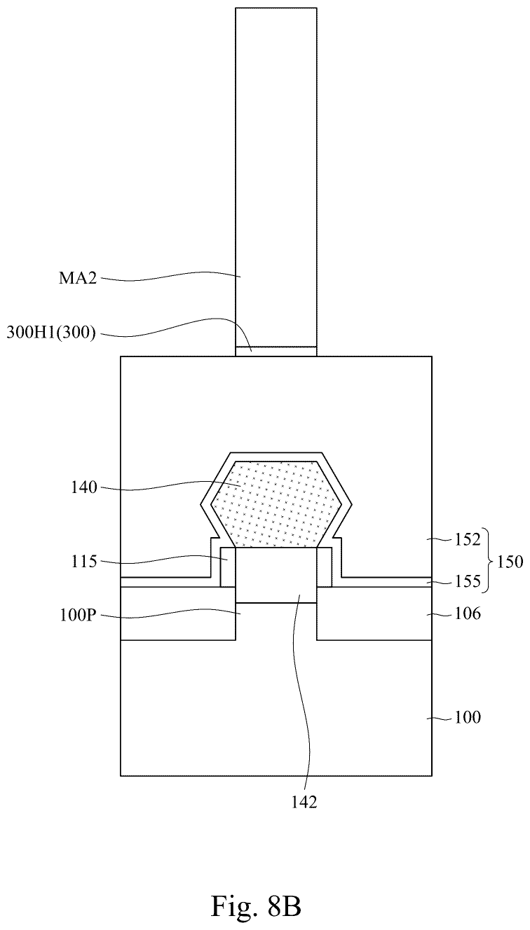

Reference is made to FIGS. 8A and 8B. A patterned mask MA2 is formed over the substrate 100. The patterned mask MA2 may be a photoresist, and may be formed by, for example, forming a resist layer over the substrate 100, exposing the resist layer to a pattern, performing post-exposure bake processes, and developing the resist layer to form the patterned mask MA2.

In the cross-sectional view of FIG. 8A, the patterned mask MA2 may cover the dummy gate structure 130, the spacers 115, and the isolation structures 150. In greater detail, the patterned mask MA2 may be in contact with the patterned mask MA1, the spacers 115, the semiconductor layer 202, and the inner spacers 116. In some embodiments, the horizontal portion 300H1 may be in contact with the inner spacers 116 in the cross-sectional view of FIG. 8A.

In the cross-sectional view of FIG. 8B, the patterned mask MA2 may cover the first source/drain epitaxy structure 140. In greater detail, the patterned mask MA2 may be vertically above the first source/drain epitaxy structure 140. The patterned mask MA2 may include openings O2.

An etching process may be performed through the openings O2 of the patterned mask MA2 to remove portions of the horizontal portion 300H1 that are not covered by the patterned mask MA2. After the etching process is complete, portions of top surface of the isolation structure 150 may be exposed. In some embodiments, the etching process remove at least portion of the horizontal portion 300H1 that does not vertically overlap the first source/drain epitaxy structure 140, leaving the remaining portion of the horizontal portion 300H1 vertically overlap the first source/drain epitaxy structure 140.

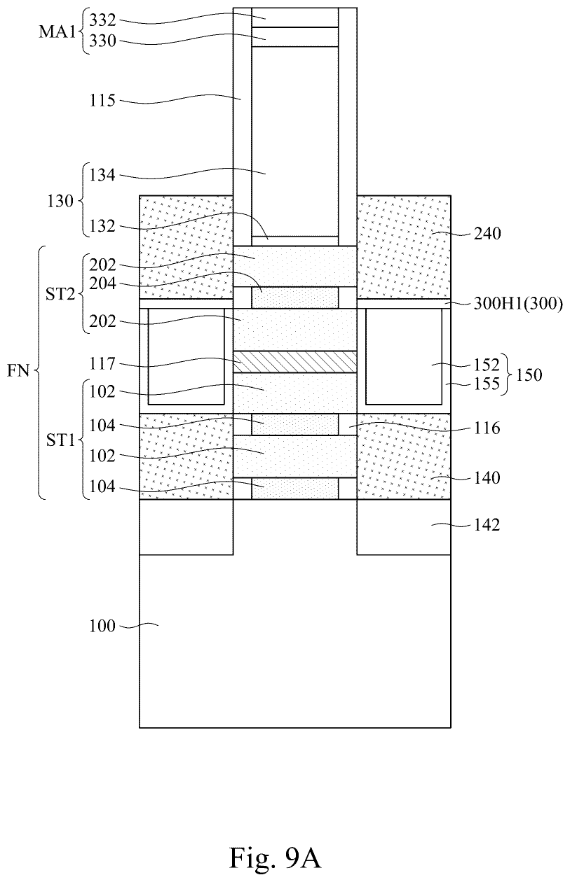

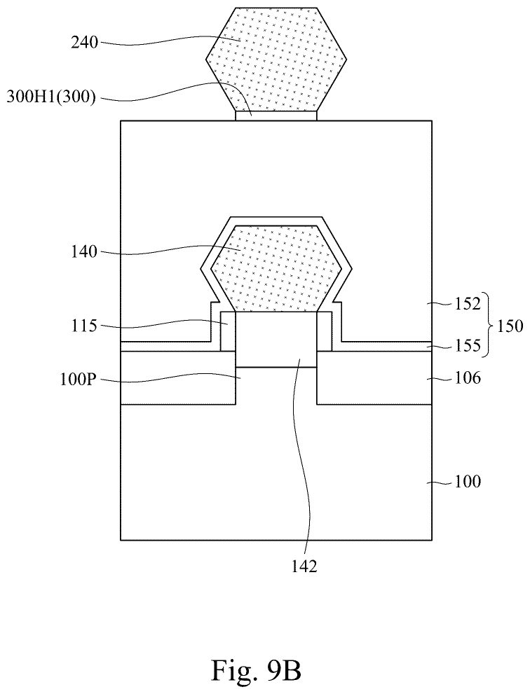

Reference is made to FIGS. 9A and 9B. The patterned mask MA2 is removed, so as to expose the remaining portion of the horizontal portion 300H1 of the seed layer 300. The patterned mask MA2 can be removed using suitable method, such as stripping or ashing.

After the patterned mask MA2 is removed, second source/drain epitaxy structures 240 are formed on opposite ends of the exposed semiconductor layer 202 and over the seed layer 300. In some embodiments, the seed layer 300 may be in contact with bottom surfaces of the second source/drain epitaxy structures 240, while sidewalls of the second source/drain epitaxy structures 240 may be free of coverage by the seed layer 300. In some embodiments, the second source/drain epitaxy structures 240 may include semiconductor material, such as silicon phosphide (SiP), or other suitable semiconductor material. The second source/drain epitaxy structures 240 may include a material different from the material of the seed layer 300. In some embodiments, the second source/drain epitaxy structures 240 may be doped with n-type dopants, such as phosphorus (P), arsenic (As), or antimony (Sb), or the like. In other embodiments, the second source/drain epitaxy structures 240 may be doped with p-type dopants, such as boron (B), gallium (Ga), indium (In), aluminium (Al), or the like. In some embodiments, the seed layer 300 may be un-doped, and thus the dopant concentration of the second source/drain epitaxy structures 240 may be higher than the dopant concentration of the seed layer 300.

In some embodiments, the second source/drain epitaxy structures 240 may be formed using a solid-phase epitaxial growth process (which may also be referred to herein as a “regrowth” process). During the solid-phase epitaxial growth process, the material of the second source/drain epitaxy structures 240 may begin to grow from the exposed surface of the semiconductor layer 202. On the other hand, the temperature of the solid-phase epitaxial growth process may also be high enough to recrystallize the amorphous structure of the seed layer 300 into a crystalline structure. Then, the material of the second source/drain epitaxy structures 240 may proceed to grow from the crystallized surface of the seed layer 300. The crystallized surface will help the epitaxial growth of the semiconductor material of the second source/drain epitaxy structures 240. Accordingly, the semiconductor material can not only be grown laterally from the exposed semiconductor layer 202, but also be grown upwardly from the horizontal surface of the seed layer 300, which is beneficial for forming void-free second source/drain epitaxy structures 240.

In other some embodiments, an annealing process may be performed prior to forming the second source/drain epitaxy structures 240, so as to recrystallize the amorphous structure of the seed layer 300 into a crystalline structure. The second source/drain epitaxy structures 240 may then be formed by a selective epitaxial growth (SEG) process. The SEG process may selectively grow a semiconductor material on exposed semiconductor surfaces, such as the exposed surfaces of the exposed semiconductor layer 202. As mentioned above, the seed layer 300 is recrystallized into a crystalline structure, such crystallized surface will help the epitaxial growth of the semiconductor material of the second source/drain epitaxy structures 240. Accordingly, the semiconductor material can not only be grown laterally from the exposed semiconductor layer 202, but also be grown upwardly from the horizontal surface of the seed layer 300, which is beneficial for forming void-free second source/drain epitaxy structures 240.

However, in some embodiments where the seed layer 300 is absent, the semiconductor material of the second source/drain epitaxy structures 240 can only grown laterally from the exposed semiconductor layer 202, the semiconductor material may seal at the top of the source/drain openings O1 and therefore create voids under the respective second source/drain epitaxy structures 240, which will result in an unsatisfying profile of the second source/drain epitaxy structures 240.

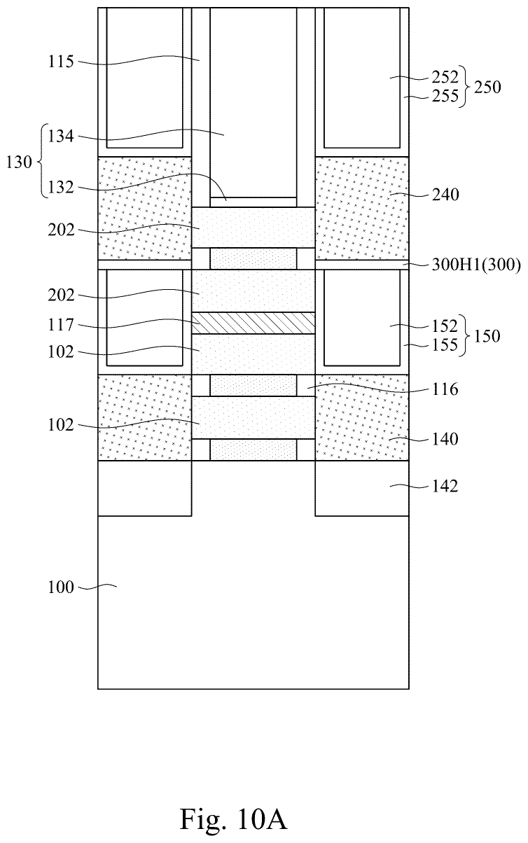

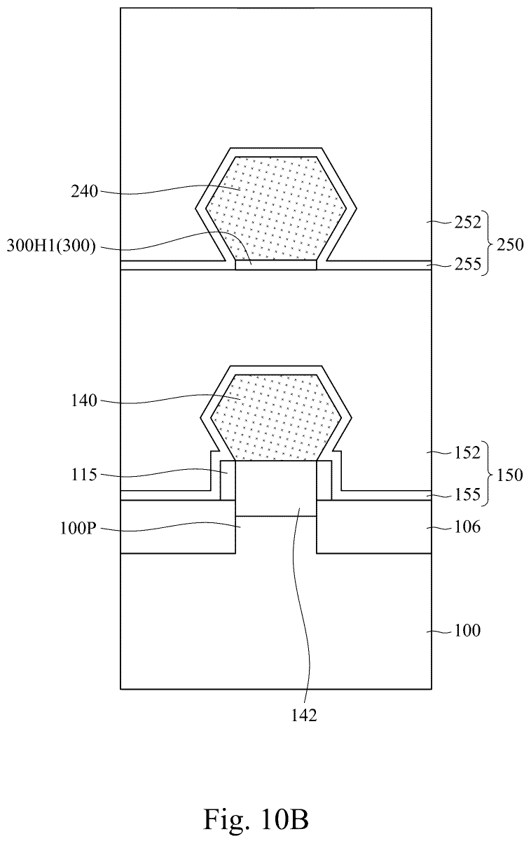

Reference is made to FIGS. 10A and 10B. A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structure 130 is exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity.

In the cross-sectional view of FIG. 10A, the isolation structures 250 may be vertically spaced apart from the seed layer 300 through the respective second source/drain epitaxy structures 240. That is, in the cross-sectional view of FIG. 10A, the bottommost end of the isolation structures 250 may be higher than the topmost end of the seed layer 300.

In the cross-sectional view of FIG. 10B, the CESL 255 of the isolation structure 250 may extend along the surface of the second source/drain epitaxy structure 240 to a sidewall of the seed layer 300, and may be in contact with the isolation structure 150. In some embodiments, the bottommost surface of the CESL 255 of the isolation structure 250 may be substantially coterminous with the bottommost surface of the seed layer 300 in the cross-sectional view of FIG. 10B.

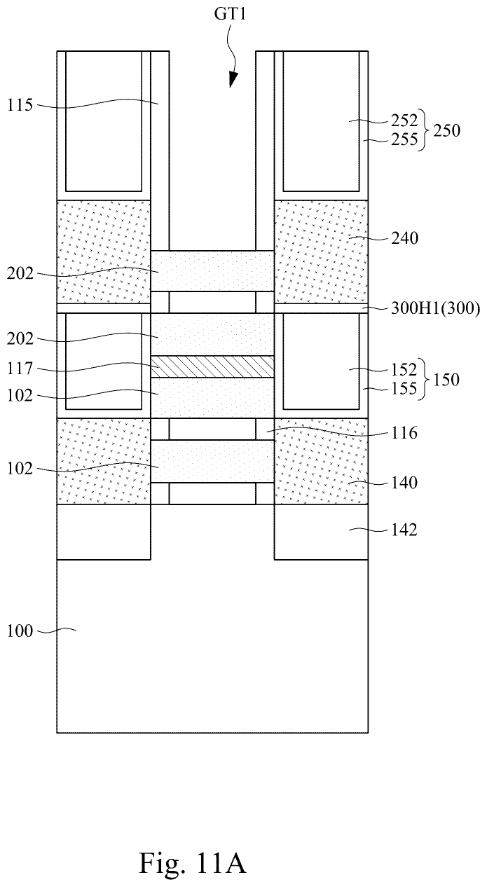

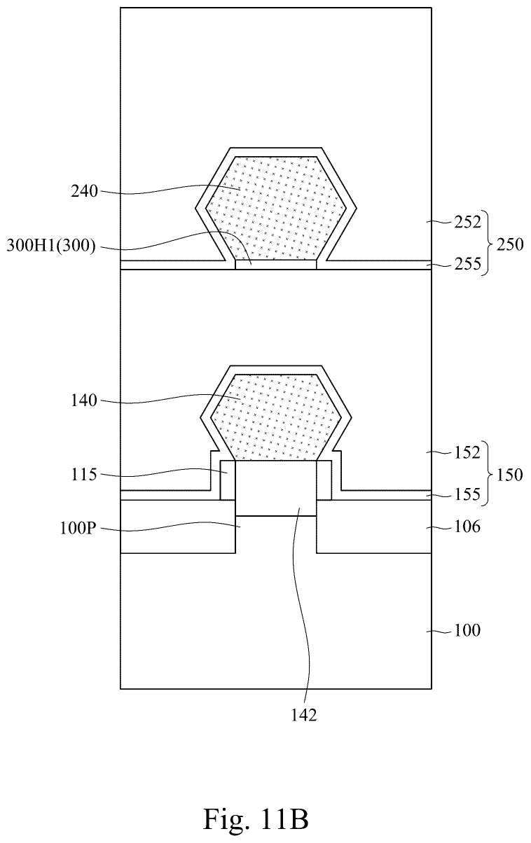

Reference is made to FIGS. 11A and 11B. The dummy gate structure 130 is removed to form gate trench GT1 between the gate spacers 115. Then, an etching process is performed to remove the semiconductor layers 104 and 204, such that at least the topmost one of the semiconductor layers 202 and at least the bottommost one of the semiconductor layers 102 are suspended over the substrate 100.

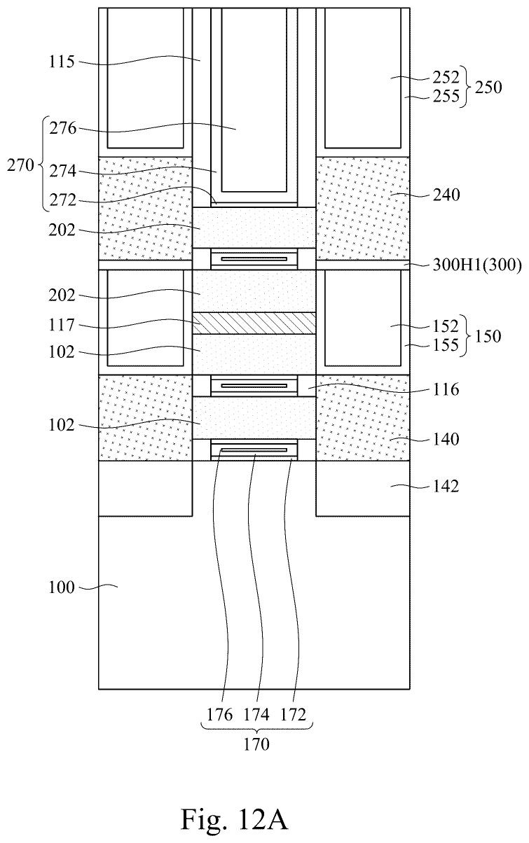

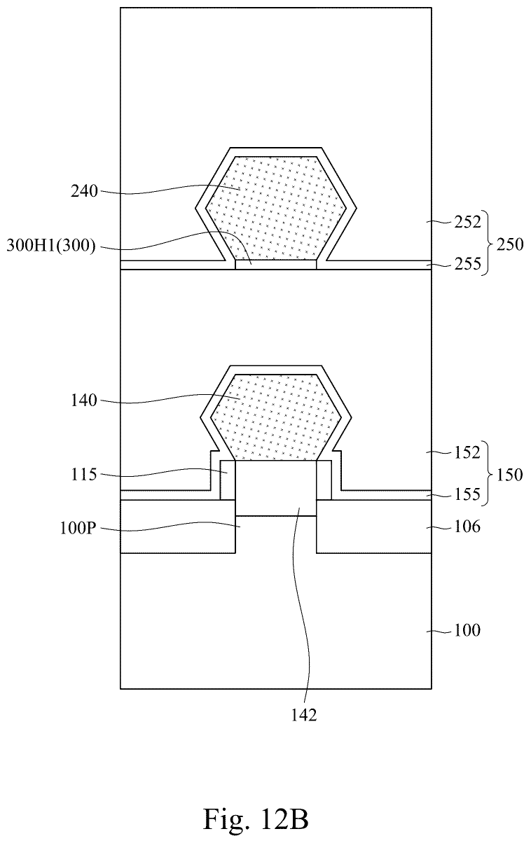

Reference is made to FIGS. 12A and 12B. Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 and 276 are formed in the gate trench GT1 and over the gate dielectric layers 174 and 274, respectively. In some embodiments, the gate electrodes 176 and 276 may include a same material or different materials. In the embodiments where the gate electrodes 176 and 276 are made of different materials, the gate electrode 176 is formed in the gate trench GT1, the gate electrode 176 is then etched back, such that the remaining gate electrode 176 is at the lower portion of the gate trench GT1. Afterwards, the gate electrode 276 is then formed in the upper portion of the gate trench GT1 and over the gate dielectric layers 274.

Accordingly, first metal gate structure 170 and second metal gate structure 270 are formed. In greater detail, the first metal gate structure 170 is formed in bottom portion of the gate trench GT1, such that the first metal gate structure 170 may wrap around the respective semiconductor layer 102. The second metal gate structure 270 is formed in upper portion of the gate trench GT1 and above the first metal gate structure 170, such that the second metal gate structure 270 may wrap around the respective semiconductor layer 202. In some embodiments, the first metal gate structure 170 may include the interfacial layer 172, the gate dielectric layer 174 over the interfacial layer 172, and the gate electrode 176 over the gate dielectric layer 174. The second metal gate structure 270 may include the interfacial layer 272, the gate dielectric layer 274 over the interfacial layer 272, and the gate electrode 276 over the gate dielectric layer 274.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a CFET. A seed layer is formed over an isolation structure prior to forming the top source/drain structures. Accordingly, the semiconductor material can not only be grown laterally from the top semiconductor channel layer, but also be grown upwardly from the seed layer, which is beneficial for forming void-free top source/drain epitaxy structures. With such configuration, the device performance may be improved.

In some embodiments of the present disclosure, a method includes forming a first semiconductor layer over a substrate and a second semiconductor layer stacked above the first semiconductor layer; epitaxially growing first source/drain epitaxy structures from opposite ends of the first semiconductor layer; forming a first isolation structure covering the first source/drain epitaxy structures; forming a seed layer over the first isolation structure; epitaxially growing second source/drain epitaxy structures from opposite ends of the second semiconductor layer and from a top surface of the seed layer; and forming a first gate structure wrapping around at least one of the first semiconductor layers and a second gate structure wrapping around at least one of the second semiconductor layers.

In some embodiments, the method further includes forming a second isolation structure covering the second source/drain epitaxy structures, wherein the second isolation structure is in contact with the seed layer in a cross-sectional view.

In some embodiments, the method further includes forming a patterned mask over the seed layer; removing a portion of the seed layer exposed by the patterned mask; and removing the patterned mask after removing the portion of the seed layer.

In some embodiments, the method further includes forming a dummy gate structure over the first semiconductor layer and the second semiconductor layer; forming gate spacers along sidewalls of the dummy gate structure, wherein forming the seed layer comprises depositing a seed material having a horizontal portion along the first isolation structure and a vertical portion along the gate spacers; and performing an etching process to remove the vertical portion of the seed material, leaving the horizontal portion of the seed material remaining as the seed layer.

In some embodiments, the horizontal portion of the seed material is thicker than the vertical portion of the seed material.

In some embodiments, the seed layer is made of a silicon-containing material.

In some embodiments, the seed layer is made of a metal-containing material.

In some embodiments of the present disclosure, a method includes forming a first semiconductor layer over a substrate and a second semiconductor layer stacked above the first semiconductor layer; forming first source/drain epitaxy structures on opposite ends of the first semiconductor layer; forming a first isolation structure covering the first source/drain epitaxy structures; depositing a seed material having a horizontal portion along the first isolation structure and a vertical portion along the second semiconductor layer; performing an etching process to remove the vertical portion of the seed layer to expose the second semiconductor layer, leaving the horizontal portion of the seed material remaining over the first isolation structure; forming second source/drain epitaxy structures on opposite ends of the second semiconductor layer and on a top surface of the horizontal portion of the seed layer; and forming a first gate structure wrapping around at least one of the first semiconductor layers and a second gate structure wrapping around at least one of the second semiconductor layers.

In some embodiments, the method further includes after performing the etching process, forming a patterned mask over the horizontal portion of the seed layer; removing a portion of the horizontal portion of the seed layer exposed by the patterned mask; and removing the patterned mask after removing the portion of the horizontal portion of the seed layer.

In some embodiments, the horizontal portion of the seed layer is thicker than the vertical portion of the seed layer.

In some embodiments, the method further includes forming a second isolation structure covering the second source/drain epitaxy structures, wherein the second isolation structure and the horizontal portion of the seed layer are both in contact with the first isolation structure in a cross-sectional view.

In some embodiments, a bottom surface of the second isolation structure is coterminous with a bottom surface of the seed layer in the cross-sectional view.

In some embodiments, the seed layer is made of a silicon-containing material.

In some embodiments, the seed layer is made of a metal-containing material.

In some embodiments of the present disclosure, a device includes a first transistor over a substrate and comprising a first semiconductor layer, first source/drain epitaxy structures on opposite ends of the first semiconductor layer, and a first gate structure wrapping around the first semiconductor layer. A second transistor is vertically stacked above the first transistor and comprises a second semiconductor layer, second source/drain epitaxy structures on opposite ends of the second semiconductor layer, a second gate structure wrapping around the second semiconductor layer. A first isolation structure covers the first source/drain epitaxy structures. A seed layer is between the first isolation structure and the second source/drain epitaxy structures.

In some embodiments, the seed layer is made of a semiconductor material.

In some embodiments, the seed layer is made of a metal-containing material.

In some embodiments, the seed layer is spaced apart from the second semiconductor layer.

In some embodiments, the device further includes a second isolation structure covering the second source/drain epitaxy structures, wherein the second isolation structure is in contact with the seed layer in a cross-sectional view.

In some embodiments, the seed layer is in contact with bottom surfaces of the second source/drain epitaxy structures, while sidewalls of the second source/drain epitaxy structures are free of coverage by the seed layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor layer over a substrate and a second semiconductor layer stacked above the first semiconductor layer;
epitaxially growing first source/drain epitaxy structures from opposite ends of the first semiconductor layer;
forming a first isolation structure covering the first source/drain epitaxy structures;
forming a seed layer over the first isolation structure;
epitaxially growing second source/drain epitaxy structures from opposite ends of the second semiconductor layer and from a top surface of the seed layer; and
forming a first gate structure wrapping around at least one of the first semiconductor layers and a second gate structure wrapping around at least one of the second semiconductor layers.

2. The method of claim 1, further comprising forming a second isolation structure covering the second source/drain epitaxy structures, wherein the second isolation structure is in contact with the seed layer in a cross-sectional view.

3. The method of claim 1, further comprising:
forming a patterned mask over the seed layer;
removing a portion of the seed layer exposed by the patterned mask; and
removing the patterned mask after removing the portion of the seed layer.

4. The method of claim 1, further comprising:
forming a dummy gate structure over the first semiconductor layer and the second semiconductor layer; and
forming gate spacers along sidewalls of the dummy gate structure, wherein forming the seed layer comprises:
depositing a seed material having a horizontal portion along the first isolation structure and a vertical portion along the gate spacers; and
performing an etching process to remove the vertical portion of the seed material, leaving the horizontal portion of the seed material remaining as the seed layer.

5. The method of claim 4, wherein the horizontal portion of the seed material is thicker than the vertical portion of the seed material.

6. The method of claim 1, wherein the seed layer is made of a silicon-containing material.

7. The method of claim 1, wherein the seed layer is made of a metal-containing material.

8. A method, comprising:
forming a first semiconductor layer over a substrate and a second semiconductor layer stacked above the first semiconductor layer;
forming first source/drain epitaxy structures on opposite ends of the first semiconductor layer;
forming a first isolation structure covering the first source/drain epitaxy structures;
depositing a seed layer having a horizontal portion along the first isolation structure and a vertical portion along the second semiconductor layer;
performing an etching process to remove the vertical portion of the seed layer to expose the second semiconductor layer, leaving the horizontal portion of the seed layer remaining over the first isolation structure;
forming second source/drain epitaxy structures on opposite ends of the second semiconductor layer and on a top surface of the horizontal portion of the seed layer; and
forming a first gate structure wrapping around at least one of the first semiconductor layers and a second gate structure wrapping around at least one of the second semiconductor layers.

9. The method of claim 8, further comprising:
after performing the etching process, forming a patterned mask over the horizontal portion of the seed layer;
removing a portion of the horizontal portion of the seed layer exposed by the patterned mask; and
removing the patterned mask after removing the portion of the horizontal portion of the seed layer.

10. The method of claim 8, wherein the horizontal portion of the seed layer is thicker than the vertical portion of the seed layer.

11. The method of claim 8, further comprising forming a second isolation structure covering the second source/drain epitaxy structures, wherein the second isolation structure and the horizontal portion of the seed layer are both in contact with the first isolation structure in a cross-sectional view.

12. The method of claim 11, wherein a bottom surface of the second isolation structure is coterminous with a bottom surface of the seed layer in the cross-sectional view.

13. The method of claim 8, wherein the seed layer is made of a silicon-containing material.

14. The method of claim 8, wherein the seed layer is made of a metal-containing material.

15. A device, comprising:
a first transistor over a substrate and comprising:
a first semiconductor layer;
first source/drain epitaxy structures on opposite ends of the first semiconductor layer; and
a first gate structure wrapping around the first semiconductor layer;
a second transistor vertically stacked above the first transistor and comprising:
a second semiconductor layer;
second source/drain epitaxy structures on opposite ends of the second semiconductor layer; and
a second gate structure wrapping around the second semiconductor layer;
a first isolation structure covering the first source/drain epitaxy structures; and
a seed layer between the first isolation structure and the second source/drain epitaxy structures.

16. The device of claim 15, wherein the seed layer is made of a semiconductor material.

17. The device of claim 15, wherein the seed layer is made of a metal-containing material.

18. The device of claim 15, wherein the seed layer is spaced apart from the second semiconductor layer.

19. The device of claim 15, further comprising a second isolation structure covering the second source/drain epitaxy structures, wherein the second isolation structure is in contact with the seed layer in a cross-sectional view.

20. The device of claim 15, wherein the seed layer is in contact with bottom surfaces of the second source/drain epitaxy structures, while sidewalls of the second source/drain epitaxy structures are free of coverage by the seed layer.
